(19) United States
(12) Patent Application Publication
(10) Pub. No.: US 2006/0205200 A1
(43) Pub. Date: Sep. 14, 2006

(54) Low capacitance solder bump interface structure

(76) Inventor: Dominick Richiuso, Saratoga, CA (US)

Correspondence Address: PILLSBURY WINTHROP SHAW PITTMAN LLP, P.O. BOX 10500, MCLEAN, VA, 22102, US

(21) Appl. No.: 11/371,175

(22) Filed: Mar. 8, 2006

Related U.S. Application Data
(60) Provisional application No. 60/659,836, filed on Mar. 8, 2005.

(51) Int. Cl. H01L 21/44

(52) U.S. Cl. 438/613

(57) ABSTRACT

A method for controlling capacitance associated with solder sphere bumps is provided. An improved structure is proposed which uses a much smaller pad on an IC with standard chip dielectric and passivation layers. An additional thick dielectric layer is then applied to the structure and a small via is opened in this thick dielectric layer. An under bump metal (UBM) is deposited and defined to provide a chip to solder sphere bump interface and an electrical connection between the pad and the solder sphere bump. The solder sphere bump can then be attached and reflowed to the UBM. Practical implementations of the invention typically obtain factors of reduction in capacitance of at least 10-20.

### CROSS-REFERENCE TO RELATED APPLICATIONS

The present application claims priority from provisional patent application No. 60/659,836 entitled “Low Capacitance Solder Bump Interface Structure,” filed Mar. 8, 2005 which is incorporated herein by reference and for all purposes.

### BACKGROUND OF THE INVENTION

1. Description of Related Art

Integrated Circuit devices (“ICs”) incorporating wafer level, flip chip or CSP packaging techniques which require direct attach to a printed circuit board without the use of underfill make use of large solder sphere bumps for the interface connections. Many high speed applications using these circuits also dictate that the capacitance of the circuit be minimized so as to maintain signal integrity.

When used in the fabrication of ICs, large solder sphere bumps, capacitance contribution due to the large solder sphere bump at the interface makes it difficult or impossible to achieve the above mentioned criteria. As shown in FIG. 1, in a conventional solder bump structure, the interface pad on the chip is approximately the same size as the solder sphere bump and sits above a silicon dioxide or silicon nitride dielectric layer. The pad-dielectric-substrate forms a capacitance which is attributable to the interface structure and is in proportion to the area of the interface.

### BRIEF SUMMARY OF THE INVENTION

The present invention addresses problems associated with capacitance present at solder bump interfaces in ICs. The invention provides methods to produce a solder bump that exhibits lower capacitance attributable to the location and fabrication of the solder sphere bump. In certain embodiments, a base or end of a solder bump can be separated from an IC using a thick, extra dielectric layer. In many embodiments, the end of the solder bump can be attached to an under-bump metal, a portion of which is attached to a metal interface pad on the surface of an upper dielectric layer of the IC.

### BRIEF DESCRIPTION OF THE DRAWINGS

These and other aspects and features of the present invention will become apparent to those ordinarily skilled in the art upon review of the following description of specific embodiments of the invention in conjunction with the accompanying figures, wherein:

FIG. 1 is a prior art drawing of a spherical solder bump;

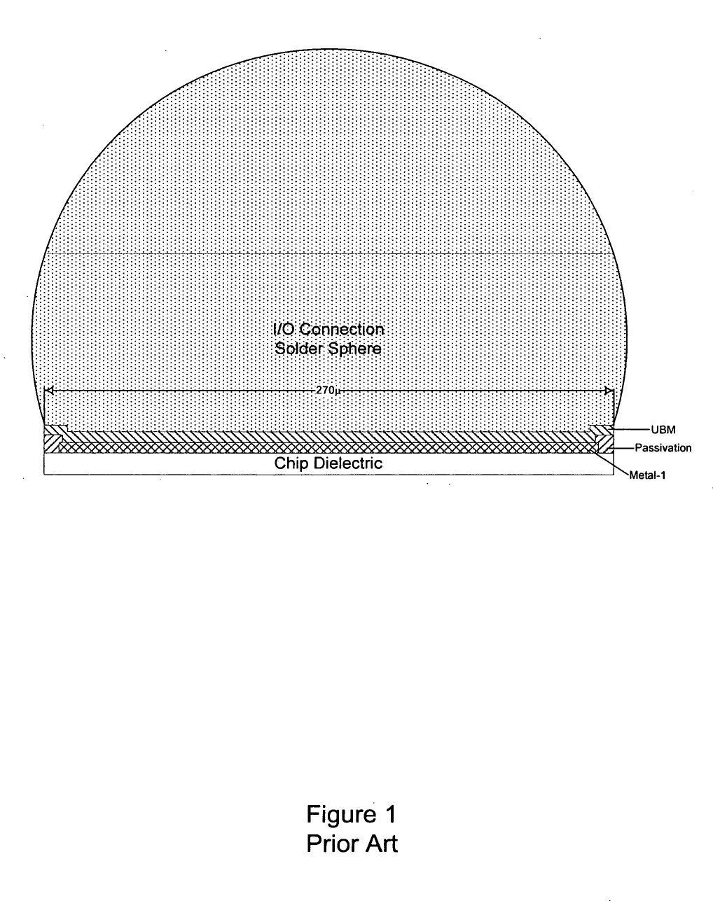

FIG. 2 depicts an embodiment in which a generally spherical solder bump is provided according to aspects of the present invention; and

FIG. 3 depicts an embodiment in which a portion of an IC containing devices and multiple solder bumps.

### DETAILED DESCRIPTION OF THE INVENTION

Embodiments of the present invention will now be described in detail with reference to the drawings, which are provided as illustrative examples so as to enable those skilled in the art to practice the invention. Notably, the figures and examples below are not meant to limit the scope of the present invention. Where certain elements of these embodiments can be partially or fully implemented using known components, only those portions of such known components that are necessary for an understanding of the present invention will be described, and detailed descriptions of other portions of such known components will be omitted so as not to obscure the invention. Further, the present invention encompasses present and future known equivalents to the components referred to herein by way of illustration.

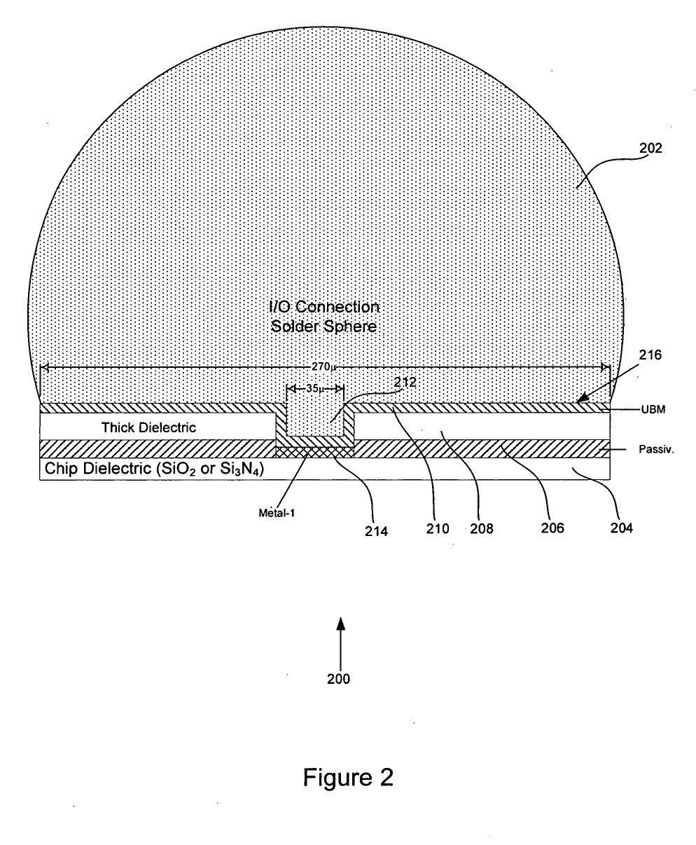

Referring to FIG. 2, an example of an embodiment of the invention is provided generally at 200. A solder bump 202 is provided for connecting portions and circuits of an IC to an external component or device, such as a circuit board (not shown). The solder bump 202 typically comprises a generally spherical dome having a largely flattened end 216 in contact with an upper surface of the IC. In the example, electrical contact is desired between the solder bump 202 and an interface pad 214 formed atop a first dielectric layer 204. Typically, pad 214 is formed on a passivated metallization layer and the pad 214 may lie generally within a passivation layer 206. First dielectric layer 204 typically insulates pad 214 from certain conductive components of the IC typically located below first dielectric layer 204. It will be appreciated that the combination of pad 214, first dielectric layer 204 and the certain conductive components can create capacitance in the structure. In certain embodiments, such as the one illustrated in FIG. 2, reduction of the area of pad 214 and addition of a thick second dielectric level 208 can increase the distance separating a substantial portion of the solder bump 202 from the first dielectric level 204. This increased separation of a substantial portion of solder bump 202 from the certain components under the first dielectric 204 can provide significant reductions in capacitance in the structure. In some embodiments, second dielectric layer can be formed using polyimide.

Pad 214 is typically created in a metallization layer on the first dielectric level 204 and can facilitate coupling of a portion of the IC to external circuitry. In many embodiments, the area presented for connection by the pad 214 can be significantly smaller than the flattened area 216 of the solder bump 202. Contact between solder bump 202 and pad 214 is typically accomplished through small via 212 opened in second dielectric layer 208 and passivation layer 206. In many embodiments, via 212 is generally cylindrical having a diameter that is at least an order of magnitude smaller than the diameter of solder sphere bump 202. After via 212 is opened, an under-bump metal (UBM) 210 can be deposited and defined such that UBM covers selected areas of the passivation layer 206, surfaces and walls of the via 212 and an upper surface of the pad 214. UBM 210 may be used as a chip-to-bump interface providing electrical coupling between interface 216 and pad 214. Solder bump 202 can be attached and reflowed to the UBM 210 to form a completed structure.

As depicted in the example of FIG. 2, the structure of solder bump 202 in relation to IC of the example can significantly reduce capacitance on a per-device level. Because a majority of the interface between solder bump 202 and IC is formed from a structure consisting of UBM 210, second dielectric 208, passivation 206 and chip dielectric substrate 204, the capacitance of the solder sphere bump interface structure can be greatly reduced. Empirical reductions in some embodiments by factors of 10-20 in interface capacitances have been obtained over prior art systems. These factors are provided as an example and it will be appreciated that per-connection capacitance reductions can be optimized by selecting various parameters including the thickness of the thick dielectric 208 and the dimensions and shape of the via 212 and pad 214.

For the purposes of illustration only, Table 1 provides some dimensions measured in one example of an embodiment of the invention. It will be appreciated that substantial variation in these dimensions is contemplated based on application requirements, materials selected and technologies employed in manufacture.

TABLE 1

| Element | Diameter | Thickness |
|---|---|---|
| Pad | 260 μm | 2 μm |
| Pad Opening | 200 μm | 10 μm |
| Passivation | 180 μm | 1 μm |
| Thick dielectric | 180 μm | 2 μm |
| Via | 42 μm | |
| Passivation opening | 32 μm | |
| UBM (Ti) | 1000 A | 240 μm |
| UBM (Cu) | 4000 A | 240 μm |
| Solder sphere | 300 μm | |

In the example of Table 1, via opening is approximately 14% of solder sphere diameter. In some embodiments factors—including, e.g., current requirements—may dictate that this percentage be set substantially higher. However, even with larger sized vias, reduced capacitance can be achieved by selecting a suitably thick dielectric layer 208. It will be further appreciated that thickness of dielectric layer 208 can be adjusted to obtain a desired reduction in capacitance.

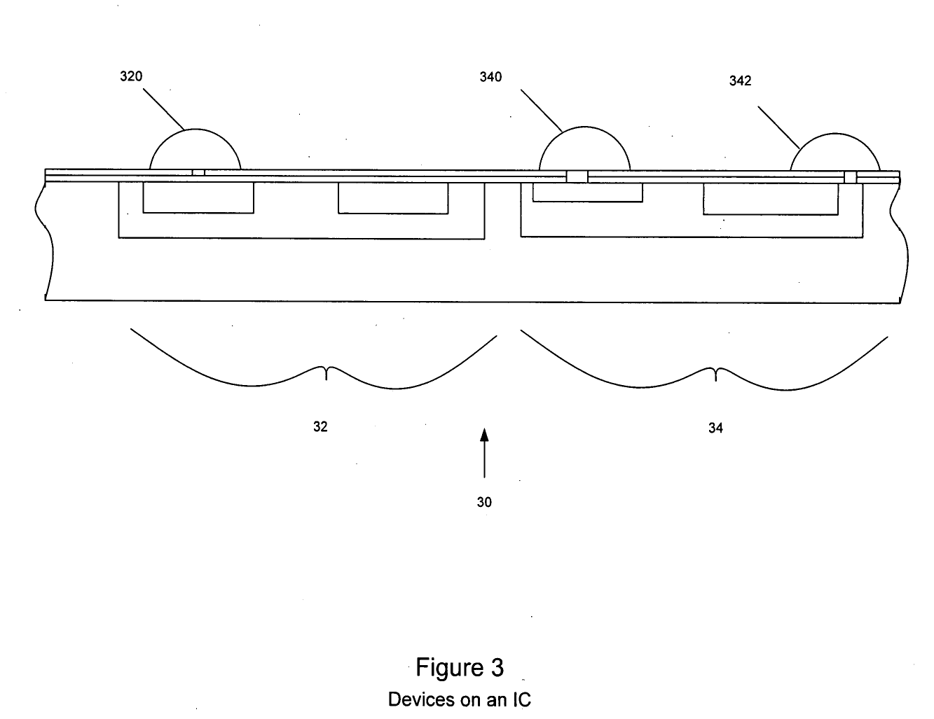

Referring to FIG. 3, it will be appreciated that the invention permits the control of capacitance on individual connections or groups of connections. FIG. 3 shows a slice of an IC 30 containing portions of devices 32 and 34. The devices 32 and 34 may be any electronic component formed on the IC 30 including transistors, diodes, resistors and memories. Each device may have one or more connections provided by solder sphere bumps 320, 340 and 342. Some devices may have no such connections. The present invention permits solder sphere bump capacitance to be controlled for each solder sphere bump 320, 340 and 342, for each device 32 and 34, for each IC 30 and for groups of solder sphere bumps (not shown) such as groups that form circuits and portions of circuits on the IC 30.

It is apparent that the above embodiments may be altered in many ways without departing from the scope of the invention. Further, the invention may be expressed in various aspects of a particular embodiment without regard to other aspects of the same embodiment. Still further, various aspects of different embodiments can be combined together.

What is claimed is:

1. A method for interfacing a solder bump comprising:
forming an interface pad on a metallization layer of an IC;
providing a thick dielectric layer above the metallization layer;
opening a via in the thick dielectric layer to expose a portion of the interface pad;
depositing an under-bump metal over a desired surface area of the thick dielectric and surfaces of the via and the interface pad; and
attaching the solder bump to the under-bump metal, wherein the thick dielectric layer is operative to reduce capacitance associated with the solder bump.

2. The method of claim 1, wherein the via is further opened through a passivation layer adjacent to the metallization layer.

3. The method of claim 1, wherein a portion of the thick dielectric layer lies between the solder bump and the IC.

4. The method of claim 1, wherein the size of the via is selected to control the capacitance.

5. The method of claim 1, wherein a portion of the solder bump is extended into the via.

6. A solder bump structure comprising:
an interface pad formed in a first metallization layer on an IC;
a thick dielectric layer deposited above the first metallization layer and having a via opened to the interface pad;
a second metallization layer deposited on a selected area including a portion of a top surface of the thick dielectric layer, walls of the via and the interface pad; and
a solder bump attached in substantial contact with the second metallization layer.

7. The structure of claim 6, wherein the solder bump has a flattened end for contacting the second metallization layer, the form of the flattened end substantially corresponding to the selected area.

8. The structure of claim 7, wherein a portion of the flattened end extends into the via.

9. The structure of claim 6, wherein a passivation layer is provided below the thick dielectric laver.

10. The structure of claim 6, wherein the solder bump includes a spherical dome.

11. The structure of claim 10, wherein the via is generally cylindrical in shape.

12. The structure of claim 11, wherein the via has a diameter substantially smaller than the diameter of the spherical dome.

13. The structure of claim 11, wherein diameter of the via is selected to provide a desired reduction in structure capacitance.

14. The structure of claim 6, wherein thickness of the thick dielectric layer is selected to provide a desired reduction in structure capacitance.
